(19) United States
(12) Patent Application Publication
(10) Pub. No.: US 2007/0030050 A1
(43) Pub. Date: Feb. 8, 2007

(54) TEMPERATURE COMPENSATED BIAS SOURCE CIRCUIT

(75) Inventors: Youn Joong Lee, SEOUL (KR); Won Tae Choi, GYEONGGI-DO (KR); Chan Woo Park, GYEONGGI-DO (KR); Byung Hoon Kim, SEOUL (KR)

Correspondence Address: LOWE HAUPTMAN BERNER, LLP, 1700 DIAGONAL ROAD, SUITE 300, ALEXANDRIA, VA, 22314, US

(73) Assignee: SAMSUNG ELECTRO-MECHANICS CO., LTD., GYUNGGI-DO (KR)

(21) Appl. No.: 11/422,574

(22) Filed: Jun. 6, 2006

(30) Foreign Application Priority Data
Aug. 8, 2005 (KR) 10-2005-0072267

(51) Int. Cl. H01L 35/00

(52) U.S. Cl. 327/513; 327/539

(57) ABSTRACT

The present invention relates to a temperature-compensated bias source circuit. The temperature-compensated bias source circuit includes a bandgap reference circuit that outputs a first temperature-compensated reference voltage and a second reference voltage having a positive slope with respect to temperature; a voltage/current converter that converts the first and second reference voltages into a reference current; and an output buffer that is connected to the bandgap reference circuit and the voltage/current converter and buffers the first and second reference voltages, output by the bandgap reference circuit, so as to output to the voltage/current converter.

### CROSS-REFERENCE TO RELATED APPLICATIONS

The application claims the benefit of Korea Patent Application No. 2005-72267 filed with the Korea Industrial Property Office on Aug. 8, 2005, the disclosure of which is incorporated herein by reference.

### BACKGROUND OF THE INVENTION

1. Field of the Invention

The present invention relates to a temperature-compensated bias source circuit, in which a reference voltage compensated with respect to temperature change and a reference voltage having a positive slope with respect to temperature can be simultaneously output by adding a small number of transistors and resistances in an existing bias source circuit, thereby providing a constant current as well as a constant voltage compensated with respect to temperature change.

2. Description of the Related Art

In general, a constant voltage source and a constant current source are basic circuits which are necessarily required for an analog circuit and hybrid circuit. A reference voltage generated by the constant voltage source and a reference current source generated by the constant current source are respectively copied or scaled so as to be used as bias voltage and current of all blocks composing an IC.

Therefore, the change in the reference voltage and current means a change in bias voltage and current of all blocks composing an IC. Such a change has a direct influence on the performance of the IC. Further, the voltage characteristic of the constant voltage source and the current characteristic of the constant current source are degraded due to the difference in doping concentration occurring in a semiconductor process and the characteristic change caused by temperature. Accordingly, studies for compensating the degradation are actively being performed.

In general, however, the constant voltage source and constant current source have a complex structure and occupy a large area within a circuit. Therefore, there are many difficulties in the studies for compensating the degradation.

FIG. 1 is a circuit diagram showing a temperature-compensated bias source circuit 100 according to the related art. FIG. 2 is a circuit diagram showing a bandgap reference circuit 110 according to the related art. FIG. 3 is a diagram showing a resistance Rs of a voltage/current converter with respect to temperature according to the related art.

As shown in FIG. 1, the temperature-compensated bias source circuit 100 is composed of the bandgap reference circuit 100 which outputs a temperature-compensated reference voltage Vref, a voltage/current converter 120 which converts the reference voltage Vref into a reference current lout, and an output buffer 130 which is connected to the bandgap reference circuit 110 and the voltage/current converter 120 and buffers the reference voltage Vref output from the bandgap reference circuit 110 so as to output to the voltage/current converter 120. In the output buffer 130, the reference voltage Vref is fed back as a side input.

The voltage/current converter 120 includes a resistance Rs having a positive slope with respect to temperature. Therefore, although the reference voltage Vref which is constant with respect to temperature change is output through the bandgap reference circuit 110, the reference current lout converted through the voltage/current converter 102 changes in accordance with temperature, which makes the characteristic thereof degraded.

In the case of the resistance Rs of the voltage/current converter 120 of which the value is 40 Ωat 25° C., the resistance value increases by about 40Ω while the temperature changes from −20° C. to 120° C., which means the change rate thereof is 10%. Accordingly, the reference current lout converted through the voltage/current converter 120 also has about a change rate of 10%, which shows that the current characteristic thereof with respect to temperature is degraded.

As shown in FIG. 2, the bandgap reference circuit 110 is composed of a first current source 111 which is connected to a ground terminal VSS and includes a first transistor stage 111a composed of one transistor, a second transistor stage 111b composed of a plurality of transistors, and a first resistance 111c so as to supply a current proportional to temperature, a second current source 112 which is connected to the ground terminal VSS and includes a third transistor stage 112a composed of a plurality of transistors and a second resistance 112b so as to supply a current which is inverse proportional to temperature, a first current mirror 113 which is connected to the first current source 111 and a power supply terminal VDD so as to cause the same current to flow in the first and second transistor stages 111a and 111b of the first current source 111, a driving section 115 which is connected to the first current mirror 113, the power supply terminal VDD, and the ground terminal VSS so as to cause the first current mirror 113 to normally operate, a second current mirror 114 which is connected to the power supply terminal VDD and the first current mirror 113 so as to copy the current supplied from the first current source 111, and a summing section 116 which sums up the current supplied from the first current source 111 and the current supplied from the second current source 112.

The first current mirror 113 is composed of a first transistor 113a which is connected to the power supply terminal VDD, a second transistor which is connected to the power supply terminal VDD and the first transistor 113a and in which the same current I_{c} as that of the first transistor 113a flows, a third transistor 113c which is connected to the first transistor 113a and the first transistor stage 111 a, and a fourth transistor 113d which is connected to the second and third transistors 113b and 113c and the second transistor stage 111b and in which the same current I_{c} as that of the third transistor 113c flows. The second current mirror 114 is connected to the third transistor stage 112a of the second current source 112, the second transistor 113b of the first current mirror 113, and the power supply terminal VDD, and is composed of a plurality of transistors.

The first resistance 111c of the first current source 111 is connected between the source of the fourth transistor 113d of the first current mirror 113 and the collector of the second transistor stage 111b of the first current source 111. The second resistance 112b of the second current source 112 is connected between the drain of the second current mirror 114 and the collector of the third transistor stage 112a of the second current source 112.

However, the temperature-compensated bias source circuit according to the related art can output a reference voltage compensated with respect to temperature change, but cannot output a reference current compensated with respect to temperature change because of resistance having a positive slope with respect to temperature. Therefore, the current characteristic with respect to temperature is degraded.

### SUMMARY OF THE INVENTION

An advantage of the present invention is that it provides a temperature-compensated bias source circuit, in which a reference voltage compensated with respect to temperature change and a reference voltage having a positive slope with respect to temperature can be simultaneously output by adding a small number of transistors and resistors in an existing bias source circuit, thereby providing a constant current as well as a constant voltage compensated with respect to temperature change.

Additional aspects and advantages of the present general inventive concept will be set forth in part in the description which follows and, in part, will be obvious from the description, or may be learned by practice of the general inventive concept.

According to an aspect of the invention, a temperature-compensated bias source circuit includes a bandgap reference circuit that outputs a first temperature-compensated reference voltage and a second reference voltage having a positive slope with respect to temperature; a voltage/current converter that converts the first and second reference voltages into a reference current; and an output buffer that is connected to the bandgap reference circuit and the voltage/current converter and buffers the first and second reference voltages, output by the bandgap reference circuit, so as to output to the voltage/current converter.

The bandgap reference circuit includes a first current source that is connected to a ground terminal and includes a first transistor stage composed of one transistor, a second transistor stage composed of a plurality of transistors, and a first resistance so as to supply a current proportional to temperature; a second current source that is connected to the ground terminal and includes a third transistor stage composed of a plurality of transistors, a fourth transistor stage composed of the same number of transistors as the third transistor stage, and second and third resistances so as to supply a current which is inverse proportional to temperature; a first current mirror that is connected to the first current source and a power supply terminal so as to cause the same current to flow in the first and second transistor stages of the first current source; a driving section that is connected to the first current mirror, the power supply terminal, and the ground terminal so as to cause the first current mirror to normally operate; a second current mirror that is connected to the power supply terminal and the first current mirror so as to copy a current supplied from the first current source; and a summing section that sums up the current supplied from the first current source and the current supplied form the second current source.

The transistors composing the first and second transistor stages of the first current source are bipolar transistors.

The first current mirror includes a first transistor that is connected to a power supply terminal; a second transistor that is connected to the power supply terminal and the first transistor and in which the same current as that of the first transistor flows; a third transistor that is connected to the first transistor and the first transistor stage; and a fourth transistor that is connected to the second and third transistors and the second transistor stage and in which the same current as that of the third transistor flows.

The first and second transistors are PMOS transistors, and the third and fourth transistors are NMOS transistors.

The first resistance is connected between the source of the fourth transistor and the collector of the second transistor stage.

The transistors composing the third and fourth transistor stages of the second current source are bipolar transistors.

The second current mirror includes a fifth transistor stage that is connected to the third transistor stage, the second transistor, and a power supply terminal and is composed of a plurality of transistors; and a sixth transistor stage that is connected to the power supply terminal and the fifth transistor stage and is composed of the same number of transistors as the fifth transistor stage and in which the same current as that of the fifth transistor stage flows.

The plurality of transistors composing the fifth and sixth transistor stages are PMOS transistors.

The second resistance is connected between the drain of the fifth transistor stage and the collector of the third transistor stage.

The third resistance is connected between the drain of the sixth transistor stage and the collector of the fourth transistor stage.

The ratio of the first resistance to the second resistance is set to 1:5.

The ratio of the first resistance to the third resistance is set to be in the range of 1:6 to 1:15.

The voltage/current converter includes a resistance having a positive slope with respect to temperature.

In the output buffer, the first or second reference voltage is fed back as a side input.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a circuit diagram showing a temperature-compensated bias source circuit according to the related art;

FIG. 2 is a circuit diagram showing a bandgap reference circuit according to the related art;

FIG. 3 is a graph showing a resistance value of a voltage/current converter with respect to temperature according to the related art;

FIG. 4 is a circuit diagram showing a temperature-compensated bias source circuit according to the present invention;

FIG. 5 is a circuit diagram showing a bandgap reference circuit according to the invention;

FIG. 6A is a graph showing a first reference voltage with respect to temperature according to the invention;

FIG. 6B is a graph showing a second reference voltage with respect to temperature according to the invention;

FIG. 6C is a graph showing a reference current which is converted from the second reference voltage with respect to temperature according to the invention;

FIG. 7A is a graph showing the simulation of change in the first reference voltage in accordance with R₂/R₁;

FIG. 7B is a graph showing the simulation of change in the second reference voltage in accordance with R₃/R₁; and

FIG. 7C is a graph showing the simulation of change in the reference current which is converted from the second reference voltage in accordance with R₃/R₁.

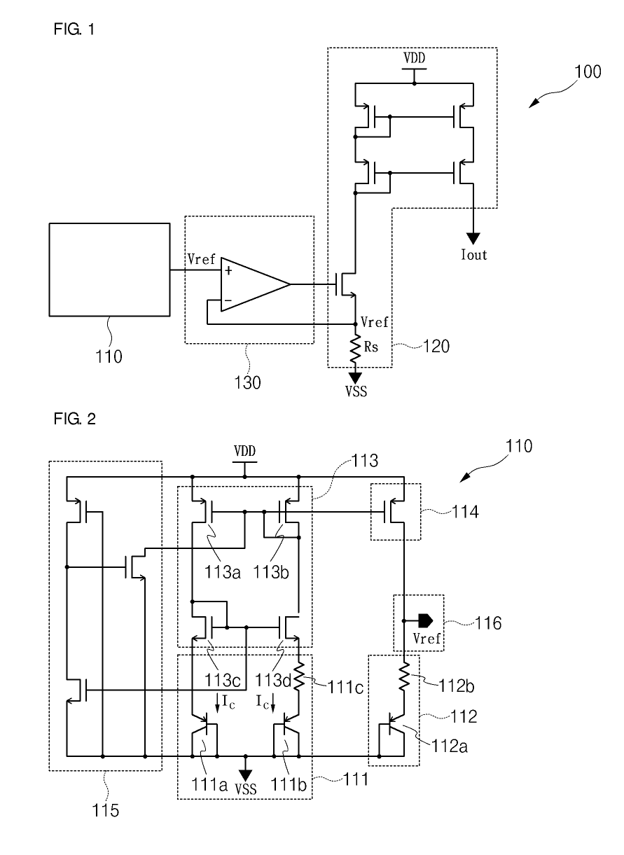

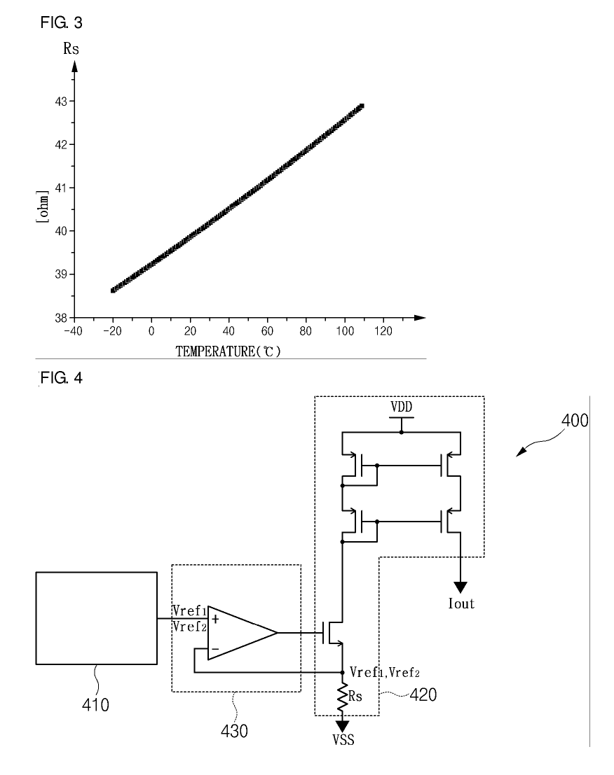

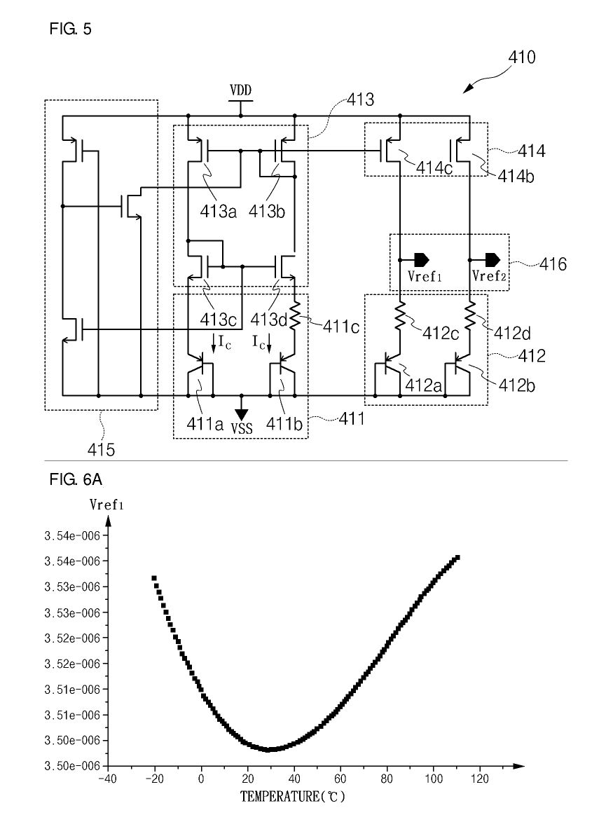

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, a preferred embodiment of the present invention will be described in detail with reference to the accompanying drawings.

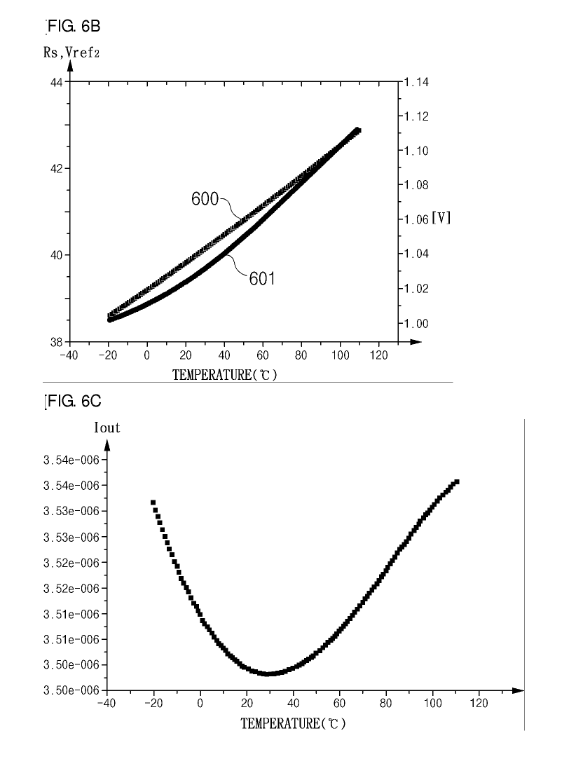

FIG. 4 is a circuit diagram showing a temperature-compensated bias source circuit 400 according to the present invention. As shown in FIG. 4, the temperature-compensated bias source circuit 400 is composed of a bandgap reference circuit 400 which outputs a first temperature-compensated reference voltage Vref1 and a second reference voltage Vref2 having a positive slope with respect to temperature, a voltage/current converter 420 which converts the first and second reference voltages Vref1 and Vref2 into a reference current lout, and a output buffer 430 which is connected to the bandgap reference circuit 410 and the voltage/current converter 420 and buffers the first and second reference voltages Vref1 and Vref2, output from the bandgap reference circuit 410, so as to output to the voltage/current converter 420. The voltage/current converter 420 includes a resistance Rs having a positive slope with respect to temperature. In the output buffer 430, the first or second reference voltage Vref1 or Vref2 is fed back as a side input.

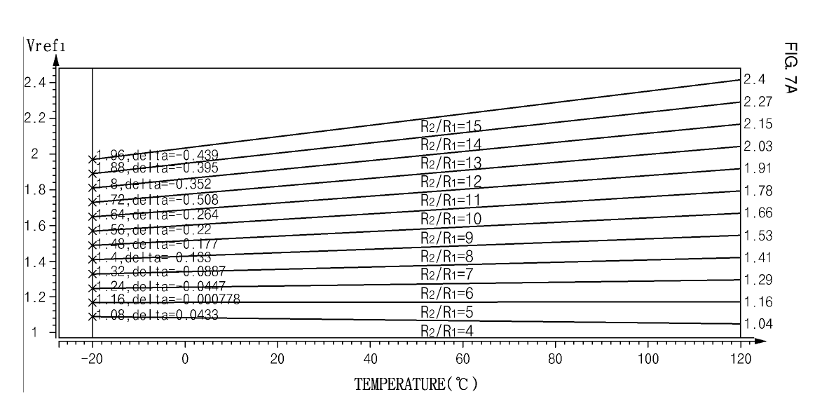

FIG. 5 is a circuit diagram showing the bandgap reference circuit 410 according to the invention. As shown in FIG. 5, the bandgap reference circuit 410 includes a first current source 411, a second current source 412, a first current mirror 413, a second current mirror 414, a driving section 415, and a summing section 416.

The first current source 411, supplying a current which is proportional to temperature, is connected to a ground terminal VSS and includes a first transistor stage 411a composed of one transistor, a second transistor stage 411 b composed of a plurality of transistors, and a first resistance 411c.

The second current source 412, supplying a current which is inverse proportional to temperature, is connected to the ground terminal VSS and includes a third transistor stage 412a composed of a plurality of transistors, a fourth transistor stage 412b composed of the same number of transistors as the third transistor stage 412a, and second and third resistances 412c and 412d.

The first current mirror 413, which is connected to the first current 411 and a power supply terminal VDD, causes the same current to flow in the first and second transistor stages 411a and 412b of the first current source 411.

The driving section 415, which is connected to the first mirror 413, the power supply terminal VDD, and the ground terminal VSS, causes the first current mirror 413 to normally operate.

The second current mirror 414, which is connected to the power supply terminal VDD and the first current mirror 413, serves to copy a current supplied from the first current source 411.

The summing section 416 serves to sum up the current supplied from the first current source 411 and the current supplied from the second current source 412.

The transistors composing the first and second transistor stages 411a and 411b of the first current source 411 and the transistors composing the third and fourth transistor stages 412a and 412b of the second current source 412 are bipolar transistors. The number of transistors composing the second transistor stage 411b of the first current source 411 is the same as the number of transistors composing the third or fourth transistor stage 412a or 412b of the second current source 412.

The first current mirror 413 is composed of a first transistor 413a which is connected to a power supply terminal VDD, a second transistor 413b which is connected to the power supply terminal VDD and the first transistor 413a and in which the same current as the first transistor 413a flows, a third transistor 413c which is connected to the first transistor 413a and the first transistor stage 411a, and a fourth transistor 413d which is connected to the second transistor 413b, the third transistor 413c, and the second transistor 411b and in which the same current as the third transistor 413c flows.

The second current mirror 414 is composed of a fifth transistor stage 414a, which is connected to the third transistor stage 412a of the second current source 412, the second transistor 413b of the first current mirror 413, and the power supply terminal VDD and is composed of a plurality of transistors, and a sixth transistor stage 414b which is connected to the power supply terminal VDD and the fifth transistor stage 414a and is composed of the same number of transistors as the fifth transistor stage 414a and in which the same current as that flowing in the fifth transistor stage 414a flows.

The first and second transistors 413a and 413b of the first current mirror 413 are PMOS transistors, and the third and fourth transistors 413c and 413d are NMOS transistors. The plurality of transistors composing the fifth and sixth transistors 414a and 414b of the second current mirror 414 are composed of PMOS transistors.

The first resistance 411c of the first current source 411 is connected between the source of the fourth transistor 413d of the first current mirror 413 and the collector of the second transistor stage 411b of the first current source 411. The second resistance 412c of the second current source 412 is connected between the drain of the fifth transistor stage 414a of the second current mirror 414 and the collector of the third transistor stage 412a of the second current source 412. The third resistance 412d of the second current source 412 is connected between the drain of the sixth transistor stage 414b of the second current mirror 414 and the collector of the fourth transistor stage 412b of the second current source 412.

The bandgap reference circuit 410 having the above-described construction can be used to output the first reference voltage Vref1 compensated with respect to temperature change and the second reference voltage Vref2 having a positive slope with respect to temperature. Further, a constant voltage source and a constant current source, compensated with respect to temperature change, are provided through the following process.

When the collector current of a general bipolar transistor is referred to as I_{c}, the collector current I_{c} satisfies the following Equation 1.
I_{C}=I_{S}e^{V}^{_{BE}}^{/V}^{_{T}} [Equation 1]

In the above equation, I_{S} means a saturation current of the bipolar transistor, V_{BE} means a base-to-emitter voltage of the bipolar transistor, and V_{T} means a threshold voltage of the bipolar transistor. In general, since V_{BE} has a slope of −0.085 mV/C° in accordance with temperature, it has a negative slope with respect to temperature change. Further, since V_{T} has a slope of +2 mV/C° in accordance with temperature, it has a positive slope with respect to temperature change.

If Equation 1 is applied to the first transistor stage 411a of the first current source 411 according to the invention and is then modified, it is possible to calculate the base-to-emitter voltage of the first transistor stage 411a. In this case, if the base-to-emitter voltage of the first transistor stage 411a is referred to as V_{BE1}, the base-to-emitter voltage _{VBE1} can be calculated through the following Equation 2.

$${V}_{BE 1} = {V}_{T} ln ( \frac{{I}_{C}}{{I}_{S}} ) \qquad [ Equation 2 ]$$

As in Equation 1, it is also possible to calculate the base-to-emitter voltage of the second transistor stage 411b of the first current source 411. In this case, if the base-to-emitter voltage of the second transistor stage 411b is referred to as V_{BE2} and the second transistor stage 411b is composed of N bipolar transistors, the base-to-emitter voltage V_{BE2} can be calculated through the following Equation 3.

$${V}_{BE 2} = {V}_{T} ln ( \frac{{I}_{C}}{{NI}_{S}} ) \qquad [ Equation 3 ]$$

Through Equations 2 and 3, it is possible to calculate the difference between the base-to-emitter voltage V_{BE1} of the first transistor stage 411a of the first current source 411 and the base-to-emitter voltage V_{BE2} of the second transistor stage 411b of the first current source 411. If the difference is referred to as ΔV_{BE}, the difference AVBE can be calculated through the following Equation 4.
ΔV_{BE}=V_{T}1n(N) [Equation 4]

Here, the collector current I_{c} flowing in the second transistor stage 411b of the first current source 411 is the same as the current flowing in the first resistance 411c, and the same voltage as the voltage obtained in Equation 4 is applied to the first resistance 41 1c. Therefore, when the first resistance is referred to as R₁, the collector current I_{c} explained in Equation 1 can be also calculated through the following Equation 5.

$${I}_{C} = \frac{Δ {V}_{BE}}{{R}_{1}} \qquad [ Equation 5 ]$$

At this time, ΔV_{BE} is shown in the form of the threshold voltage V_{T} of the bipolar transistor, and the threshold voltage V_{T} has a positive slope with respect to temperature change. Accordingly, since the collector current I_{c} also has a positive slope with respect to temperature change, the first current source 411 serves to supply a current proportional to temperature.

Meanwhile, if the fifth transistor stage 414a of the second current mirror 414 is composed of M transistors (M is a positive integer), a current which is M times larger than the current I_{c} flowing in the first resistance 411c flows in the fifth transistor stage 414a of the second current mirror 414, because a current flowing in a MOS transistor is proportional to the number of transistors. Therefore, when the second resistance 412c is referred to as R₂ and the base-to-emitter voltage of the third transistor stage 412a of the second current source 412 is referred to as V_{BE3}, the first reference voltage Vref1 can be calculated through the following Equation 6.
V_{ref1}=V_{BE3}+MR₂(I_{c}) [Equation 6]

If Equation 6 is substituted into Equation 5, the first reference voltage Vref1 can be also calculated through the following Equation 7.

$${V}_{ref 1} = {V}_{BE 3} + \frac{{MR}_{2}}{{R}_{1}} {V}_{T} ln ( N ) \qquad [ Equation 7 ]$$

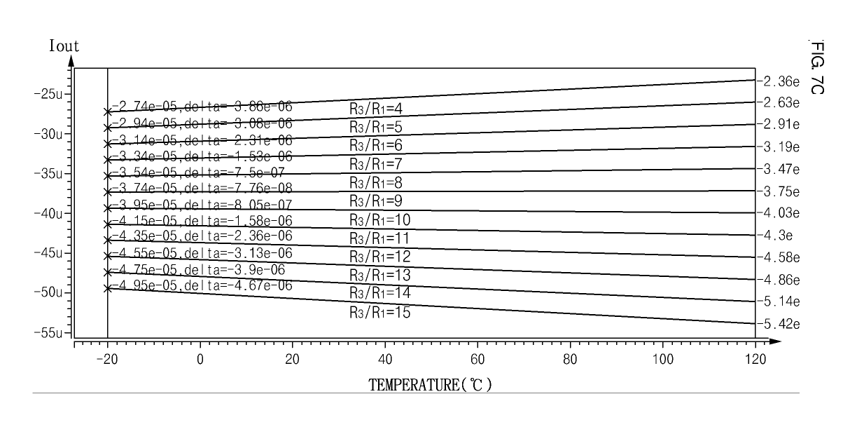

Through Equation 7 having a term of the base-to-emitter voltage, it can be found that the second current source 412 supplies a current which is inverse proportional to temperature and the first reference voltage Vref1 compensated with respect to temperature change in accordance with the ratio of the first resistance 411c to the second resistance 411c can be output. At this time, when the ratio of the first resistance 411c to the second resistance 412c is set to 1:5, the first reference voltage Vref1 compensated with respect to temperature change can be output. Further, when the ratio of the first resistance 411c to the second resistance 412c is set to 1:5, the simulation result of the first reference voltage Vref1 is shown in FIG. 7A which will be described.

When the third resistance 412d is referred to as R₃ and the base-to-emitter voltage of the fourth transistor stage 412b of the second current source 412 is referred to as V_{BE4}, the second reference voltage Vref2 can be calculated through the following Equation 8, similar to the first reference voltage Vref1.

$${V}_{ref 2} = {V}_{BE 4} + \frac{{MR}_{3}}{{R}_{1}} {V}_{T} ln ( N ) \qquad [ Equation 8 ]$$

Through Equation 8 having a term of the base-to-emitter voltage, it can be also found that the second current source 412 supplies a current which is inverse proportional to temperature and the second reference voltage Vref2 having a positive slope with respect to temperature change in accordance with the ratio of the first resistance 411c to the third resistance 412d can be output. At this time, when the ratio of the first resistance 411c to the third resistance 412d is set in the range from 1:6 to 1:15, the second reference voltage Vref2 having a positive slope with respect to temperature change can be output. Further, when the ratio of the first resistance 411 c to the third resistance 412d is set in the range from 1:6 to 1:15, the simulation result of the second reference value Vref2 is shown in FIG. 7B which will be decribed.

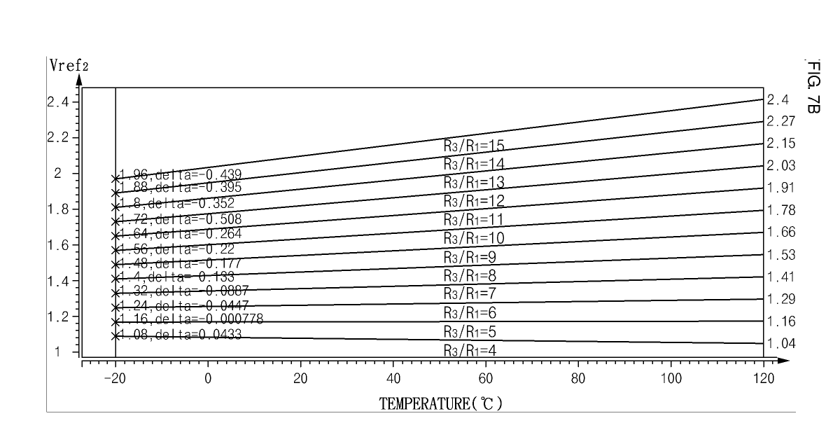

FIG. 6A is a diagram showing the first reference voltage Vref1 with respect to temperature according to the invention. FIG. 6B is a diagram showing the second reference voltage Vref2 with respect to temperature according to the invention. FIG. 6C is a diagram showing the a reference current lout in which the second reference voltage Vref2 with respect to temperature is converted.

When the ratio of the first resistance 411c to the second resistance 412c is set to an optimal value, it can be found that the first reference voltage Vref1 output through the present invention has a nearly constant value with respect to temperature change, as shown in FIG. 6A.

Further, when the ratio of the first resistance 411c to the third resistance 412d is set to an optimal value, it can be found that the second reference voltage Vref2 output through the invention has almost the same slope 601 as a slope 600 of the resistance Rs, included in a voltage/current converter, with respect to temperature, as shown in FIG. 6C. Accordingly, it is possible to output the reference current lout having a nearly constant value with respect to temperature change, as shown in FIG. 6C.

When the first resistance 411c is referred to as R₁, the second resistance 412c is referred to as R₂, and the third resistance 412d is referred to as R₃, FIG. 7A shows the simulation of change in the first reference voltage Vref1 in accordance with R₂/R₁, FIG. 7B shows the simulation of change in the second reference voltage Vref2 in accordance with R₃/R₁, and FIG. 7C shows the simulation of change in the reference current lout into which the second reference voltage Vref2 in accordance with R₃/R₁ is converted.

In FIG. 7A, when R₂/R₁ is 5, that is, when the ratio of the first resistance 411c to the second resistance 412c is 1:5, the slope of the first reference voltage Vref1 becomes 0. Therefore, it can be found that the first reference voltage is constant with respect to temperature change.

In FIG. 7B, when R₃/R₁ is in the range of 6 to 15, that is, when the ratio of the first resistance 411c to the third resistance 412d is in the range of 1:6 to 1:15, the slope of the second resistance voltage Vref2 has a positive coefficient. Accordingly, when R₃/R₁ is in the range of 6 to 15 as shown in FIG. 7C, it is possible to output the reference current lout of which the change rate with respect to temperature change is within the range of 10%.

The above-described simulation results are arranged in Tables 1 to 3. Table 1 shows the simulation result of change in the first reference voltage Vref1 in accordance with R₂/R₁. Table 2 shows the simulation result of change in the second reference voltage Vref2 in accordance with R₃/R₁. Table 3 shows the simulation result of change in the reference current he second reference voltage Vref2 in accordance with R₃/R₁ is converted.

TABLE 1

| | | | Change Rate of Vref1 |
|---|---|---|---|
| R1[kohm] | R2[kohm] | R2/R1 | [e−4 V/° C.] |
| 10 | 40 | 4 | −3.08 |
| 10 | 50 | 5 | 0 |
| 10 | 60 | 6 | 3.85 |
| 10 | 70 | 7 | 6.92 |
| 10 | 80 | 8 | 10.8 |
| 10 | 90 | 9 | 13.8 |
| 10 | 100 | 10 | 16.9 |
| 10 | 110 | 11 | 20.8 |
| 10 | 120 | 12 | 23.8 |
| 10 | 130 | 13 | 26.9 |
| 10 | 140 | 14 | 30.8 |
| 10 | 150 | 15 | 33.8 |

TABLE 2

| | | | Change Rate of Vref2 |
|---|---|---|---|
| R1[kohm] | R3[kohm] | R3/R1 | [e−4 V/° C.] |
| 10 | 40 | 4 | −3.08 |
| 10 | 50 | 5 | 0 |
| 10 | 60 | 6 | 3.85 |
| 10 | 70 | 7 | 6.92 |
| 10 | 80 | 8 | 10.8 |
| 10 | 90 | 9 | 13.8 |
| 10 | 100 | 10 | 16.9 |
| 10 | 110 | 11 | 20.8 |
| 10 | 120 | 12 | 23.8 |
| 10 | 130 | 13 | 26.9 |
| 10 | 140 | 14 | 30.8 |
| 10 | 150 | 15 | 33.8 |

TABLE 3

| | | | Change Rate of lout |
|---|---|---|---|
| R1[kohm] | R3[kohm] | R3/R1 | [%] |
| 10 | 40 | 4 | 14.23 |
| 10 | 50 | 5 | 10.54 |
| 10 | 60 | 6 | 7.32 |
| 10 | 70 | 7 | 4.5 |
| 10 | 80 | 8 | 1.98 |
| 10 | 90 | 9 | 0.27 (optimal) |
| 10 | 100 | 10 | 2.02 |
| 10 | 110 | 11 | 3.61 |
| 10 | 120 | 12 | 5.28 |
| 10 | 130 | 13 | 6.81 |
| 10 | 140 | 14 | 8.21 |
| 10 | 150 | 15 | 8.62 |

When R₂/R₁ is 5, the slope of the first reference voltage Vref1 becomes 0, as described in Table 1. When R₃/R₁ is in the range of 6 to 15, the slope of the second reference voltage Vref2 has a positive coefficient, as described in Table 2. When R₃/R₁, is in the range of 6 to 15, the change rate of the reference current lout is within the range of 10%, as described in Table 3. Particularly, when R₃/R₁ is 9, the reference current lout nearly constant with respect to temperature change is output.

According to the temperature-compensated bias source circuit of the present invention, the reference voltage compensated with respect to temperature change and the reference voltage having a positive slope with respect to temperature can be simultaneously output by adding a small number of elements, which makes it possible to provide a constant current source as well as a constant voltage source compensated with respect to temperature change.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A temperature-compensated bias source circuit comprising:
a bandgap reference circuit that outputs a first temperature-compensated reference voltage and a second reference voltage having a positive slope with respect to temperature;
a voltage/current converter that converts the first and second reference voltages into a reference current; and
an output buffer that is connected to the bandgap reference circuit and the voltage/current converter and buffers the first and second reference voltages, output by the bandgap reference circuit, so as to output to the voltage/current converter.

2. The temperature-compensated bias source circuit according to claim 1,
wherein the bandgap reference circuit includes:
a first current source that is connected to a ground terminal and includes a first transistor stage composed of one transistor, a second transistor stage composed of a plurality of transistors, and a first resistance so as to supply a current proportional to temperature;
a second current source that is connected to the ground terminal and includes a third transistor stage composed of a plurality of transistors, a fourth transistor stage composed of the same number of transistors as the third transistor stage, and second and third resistances so as to supply a current which is inverse proportional to temperature;
a first current mirror that is connected to the first current source and a power supply terminal so as to cause the same current to flow in the first and second transistor stages of the first current source;
a driving section that is connected to the first current mirror, the power supply terminal, and the ground terminal so as to cause the first current mirror to normally operate;
a second current mirror that is connected to the power supply terminal and the first current mirror so as to copy a current supplied from the first current source; and
a summing section that sums up the current supplied from the first current source and the current supplied form the second current source.

3. The temperature-compensated bias source circuit according to claim 2,
wherein the transistors composing the first and second transistor stages of the first current source are bipolar transistors.

4. The temperature-compensated bias source circuit according to claim 3,
wherein the first current mirror includes:
a first transistor that is connected to a power supply terminal;
a second transistor that is connected to the power supply terminal and the first transistor and in which the same current as that of the first transistor flows;
a third transistor that is connected to the first transistor and the first transistor stage; and
a fourth transistor that is connected to the second and third transistors and the second transistor stage and in which the same current as that of the third transistor flows.

5. The temperature-compensated bias source circuit according to claim 4, wherein the first and second transistors are PMOS transistors, and the third and fourth transistors are NMOS transistors.

6. The temperature-compensated bias source circuit according to claim 5, wherein the first resistance is connected between the source of the fourth transistor and the collector of the second transistor stage.

7. The temperature-compensated bias source circuit according to claim 6,
wherein the transistors composing the third and fourth transistor stages of the second current source are bipolar transistors.

8. The temperature-compensated bias source circuit according to claim 7,
wherein the second current mirror includes:
a fifth transistor stage that is connected to the third transistor stage, the second transistor, and a power supply terminal and is composed of a plurality of transistors; and
a sixth transistor stage that is connected to the power supply terminal and the fifth transistor stage and is composed of the same number of transistors as the fifth transistor stage and in which the same current as that of the fifth transistor stage flows.

9. The temperature-compensated bias source circuit according to claim 8,
wherein the plurality of transistors composing the fifth and sixth transistor stages are PMOS transistors.

10. The temperature-compensated bias source circuit according to claim 9,
wherein the second resistance is connected between the drain of the fifth transistor stage and the collector of the third transistor stage.

11. The temperature-compensated bias source circuit according to claim 10,
wherein the third resistance is connected between the drain of the sixth transistor stage and the collector of the fourth transistor stage.

12. The temperature-compensated bias source circuit according to claim 11,
wherein the ratio of the first resistance to the second resistance is set to 1:5.

13. The temperature-compensated bias source circuit according to claim 12,
wherein the ratio of the first resistance to the third resistance is set in the range of 1:6to 1:15.

14. The temperature-compensated bias source circuit according to claim 1,
wherein the voltage/current converter includes a resistance having a positive slope with respect to temperature.

15. The temperature-compensated bias source circuit according to claim 1,
wherein, in the output buffer, the first or second reference voltage is fed back as a side input.
